(19) United States
(12) Patent Application Publication
(10) Pub. No.: US 2004/0266075 A1
(43) Pub. Date: Dec. 30, 2004

(54) Method for fabricating a low temperature polysilicon thin film transistor

(76) Inventor: Kun-Hong Chen, Taipei County (TW)

Correspondence Address: RABIN & Berdo, PC, 1101 14TH STREET, NW, SUITE 500, WASHINGTON, DC, 20005, US

(21) Appl. No.: 10/781,778

(22) Filed: Feb. 20, 2004

(30) Foreign Application Priority Data
Jun. 30, 2003 (TW) 92117888

(51) Int. Cl. H01L 21/00

(52) U.S. Cl. 438/154

(57) ABSTRACT

A method of forming a low temperature polysilicon thin film transistor includes steps of: providing a substrate; forming a polysilicon layer on the substrate; forming a gate oxide layer on the polysilicon layer; forming a photoresist pattern on the gate oxide layer; using the photoresist pattern as a mask and etching the gate oxide layer and the polysilicon layer; removing the photoresist pattern; forming a gate on the gate oxide layer; and implanting dopants to form source/drain region by using the gate as a mask.

This application claims the benefit of Taiwan application Ser. No. 92117888, filed Jun. 30, 2003.

### BACKGROUND OF THE INVENTION

1. Field of the Invention

The invention relates in general to a method for fabricating a low temperature polysilicon thin film transistor, and more particularly to a method of fabricating a low temperature polysilicon thin film transistor without residues of photoresist and chemicals.

2. Description of the Related Art

Polysilicon and amorphous silicon are two commonly used materials for thin film transistors (TFTs). Low temperature polysilicon TFTs have the advantages of higher electron mobility and drive current over amorphous TFTs. Therefore, the development and improvement of low temperature polysilicon TFTs fabrication process are now of great demand. Within the field of improving the low temperature polysilicon TFTs fabrication process, residues of photoresist and chemicals during the photolithography and etching process is an important issue.

FIGS. 1A to 1J are cross-sectional views showing the sequential process steps of a conventional method for fabricating a low temperature polysilicon thin film transistor. Referring to FIG. 1A, a buffer layer 102 is first formed on a substrate 100 and a polysilicon layer 104 is then formed on the buffer layer 102. The polysilicon layer 104 is formed by annealing amorphous silicon, using excimer laser. Next, a patterned photoresist layer 105 is formed on the polysilicon layer 104. The polysilicon layer 104 is etched using the patterned photoresist layer 105 as a mask. The photoresist layer 105 is then removed by using chemicals, such as wet dip. The structure after wet dip is shown in FIG. 1B.

Referring to FIG. 1C, a gate oxide layer 108 is formed over the polysilicon layer 104, and a conductive layer is disposed on the gate oxide layer 108. Photolithography and etching processes are then performed to define the gate oxide layer 108 as a patterned gate 110. Next, referring to FIG. 1D, a photoresist layer 112 is formed on the gate 110 and on the gate oxide layer 108. Then, a heavily doping process, with high dosage of phosphorus, is performed to form source/drain region 104a, 104b of NMOS device of a CMOS transistor and also form source/drain region 104c, 104d of a NMOS device in a pixel area.

The photoresist layer 112 is then removed. Low dosage of phosphorus is then implanted into the substrate 100 to form lightly doped source/drain regions 104m, 104x, 104n and 104y of the NMOS transistor, as shown in FIG. 1E. Next, referring to FIG. 1F, a photoresist layer 114 is formed on the gate 110 and the gate oxide layer 108. Using the photoresist layer 114 as a mask, high dosage of boron is implanted in the substrate 100 to form source/drain region 104i, 104j of a PMOS transistor.

Referring to FIG. 1G, the photoresist layer 114 is removed. An interlayer dielectric 116 is formed on the gate 110 and on the gate oxide layer 108. There are a number of openings formed within the gate oxide layer 108 and within the interlayer dielectric 116. Then, referring to FIG. 1H, electrodes 118 are formed on the interlayer dielectric 116. The electrodes 118 fill the openings within the gate oxide layer 108 and within the interlayer dielectric 116. The electrodes 118 thereby electrically connect the source/drain regions 104a, 104c, 104i, 104b, 104d and 104j.

Referring to FIG. 11, a passivation layer 120 is formed on the electrodes 118 and the interlayer dielectric 116. An opening is formed through the passivation layer 120 to expose the electrodes 118. Next, a transparent electrode 122 is formed on the passivation layer 120. The transparent electrode 122 fills the opening within the passivation layer 120 to electrically connect the electrode 118, as shown in FIG. 1J. A structure resulting from this process is shown in FIG. 1J.

In the low temperature polysilicon TFT fabricated by the foregoing conventional method, the electron mobility is restricted due to photoresist and chemicals residues left on the polysilicon layer 104, as shown in FIG. 1B. In addition, other characteristics of the low temperature TFT, such as the value of the threshold voltage and the sub-threshold swing, can be affected by the presence of photoresist and chemicals residues remaining in the device.

### SUMMARY OF THE INVENTION

It is therefore an object of the invention to provide an improved method for fabricating a low temperature polysilicon thin film transistor without photoresist and chemicals residues.

The invention achieves the above-identified objects by providing a method for fabricating a NMOS transistor and a PMOS transistor on a substrate. The method includes the steps of: forming a buffer layer on the substrate; forming a polysilicon layer on the buffer layer, wherein the polysilicon layer preferably has a thickness between about 200 angstroms and 1000 angstroms; forming a gate oxide layer on the polysilicon layer, wherein the gate oxide layer preferably has a thickness between about 500 angstroms and 1500 angstroms; forming a photoresist pattern on the gate oxide layer; etching the polysilicon layer and the gate oxide layer and using the photoresist pattern as a mask by photolithography to form a first stack structure corresponding to the NMOS transistor and to form a second stack structure corresponding to the PMOS transistor; removing the photoresist pattern; forming a gate on the gate oxide layer, wherein the gate includes molybdenum, chromium, or thallium/aluminum/thallium; forming source/drain region of the NMOS transistor by implanting first heavy dopants and using a photoresist layer covering the second stack structure and lightly doped region of the NMOS transistor as a mask, wherein the first heavy dopants include phosphorus with the preferred dosage between about 1E14 dose/cm² and 5E15 dose/cm²; implanting dopants to form the lightly doped region of the NMOS transistor by using the gate as a mask, wherein the dopants include phosphorus with the preferred dosage between about 8E12 dose/cm² and 5E13 dose/cm²; and implanting second heavy dopants to form source/drain region of the PMOS transistor by using a photoresist layer over the first stack structure as a mask, wherein the second heavy dopants include phosphorus with the preferred dosage between about 1E14 dose/cm² and 5E15 dose/cm2.

Embodiments of the invention further includes: forming an interlayer dielectric on the gate oxide layer, the gate and the substrate, wherein the interlayer dielectric preferably has a thickness between about 2000 angstroms and 7000 angstroms; selectively exposing the gate, the source/drain regions of the NMOS transistor and the PMOS transistor; forming a patterned passivation layer on the interlayer dielectric and the electrodes, wherein the patterned passivation layer exposes a portion of the electrodes of the NMOS transistor in a pixel area; and forming a transparent electrode to electrically connect the exposed portion of the electrodes of the NMOS transistor exposed, wherein the transparent electrode includes indium tin oxide (ITO).

Other objects, features, and advantages of the invention will become apparent from the following detailed description of the preferred but non-limiting embodiments. The following description is made with reference to the accompanying drawings.

### BRIEF DESCRIPTION OF THE DRAWINGS

FIGS. 1A to 1J (Prior Art) are cross-sectional views showing the sequential process steps of a conventional method for fabricating a low temperature polysilicon thin film transistor.

FIGS. 2A to 2J are cross-sectional views showing the sequential process steps of the method for fabricating a low temperature polysilicon thin film transistor in accordance with one preferred embodiment of the present invention.

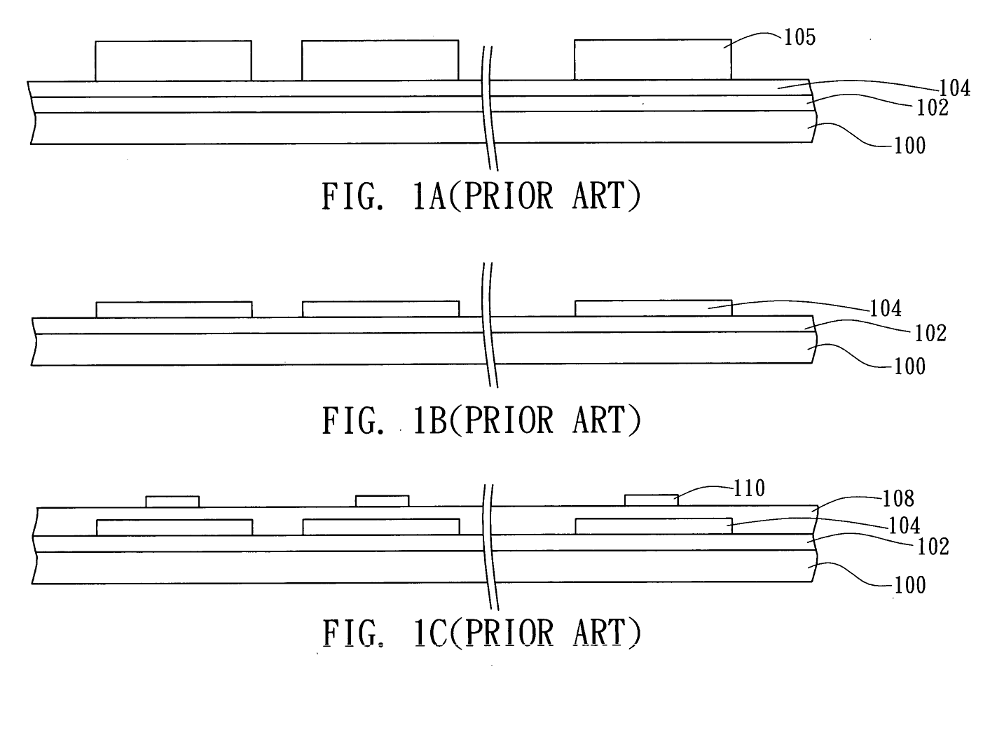

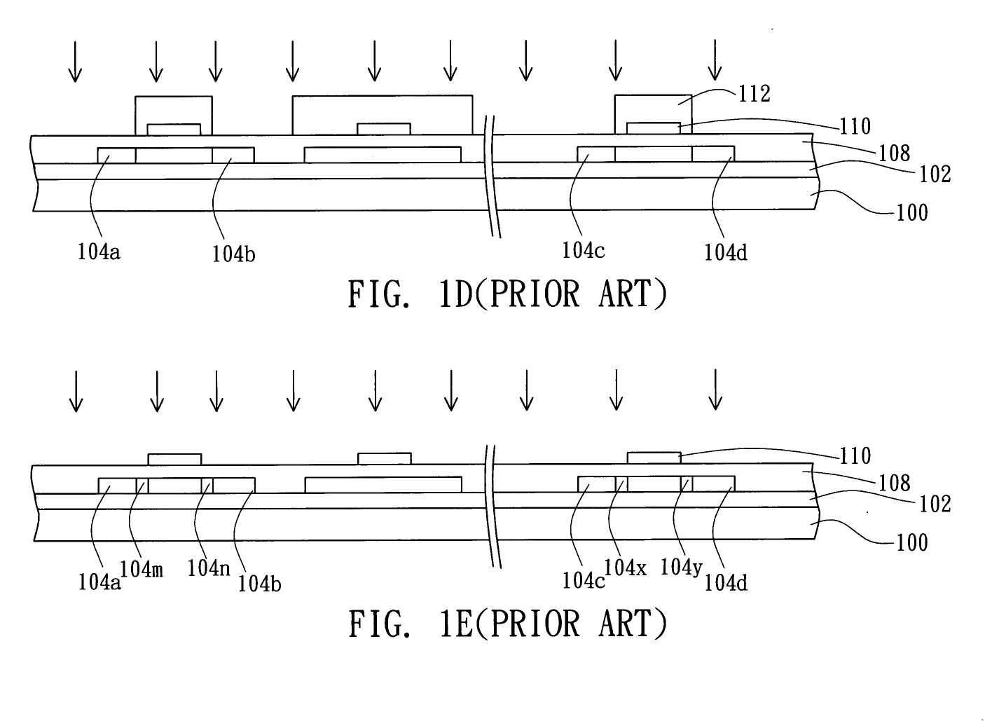

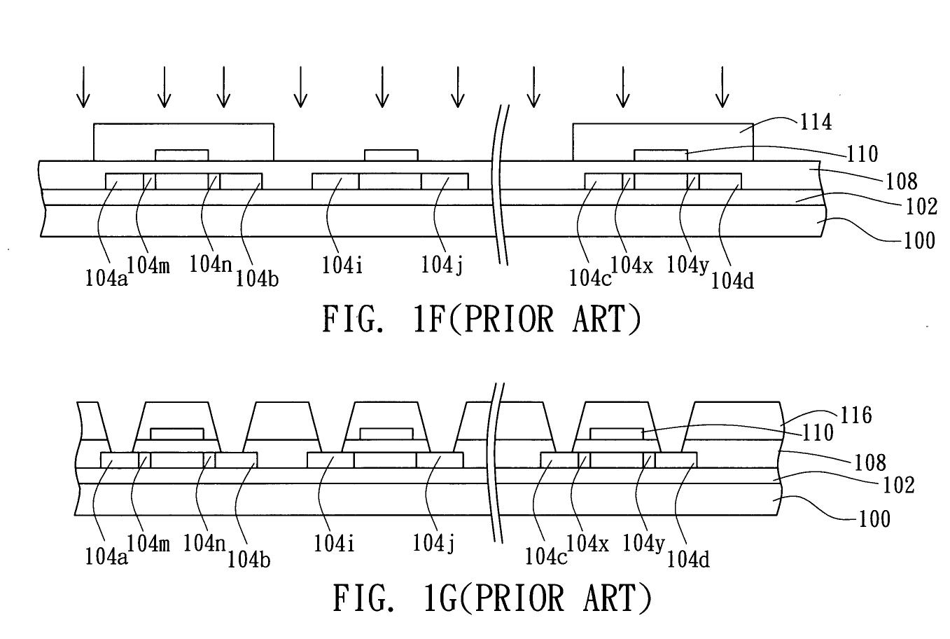

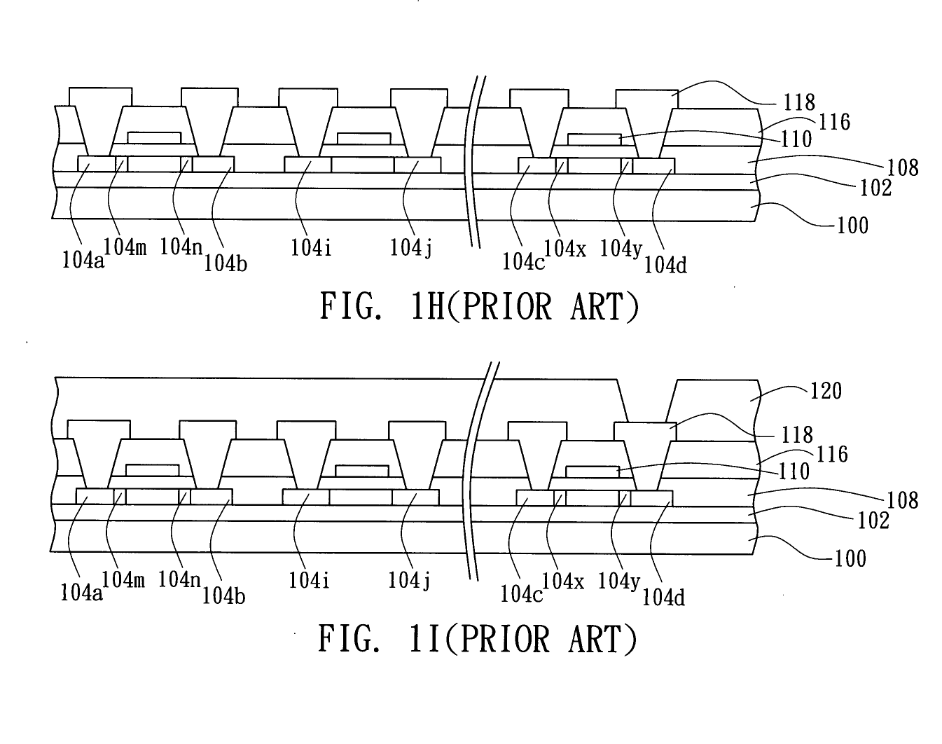

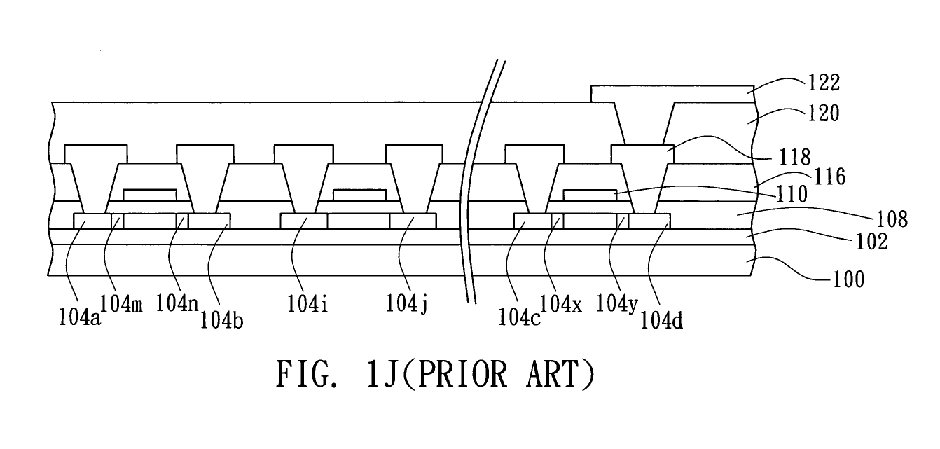

### DETAILED DESCRIPTION OF THE INVENTION

The present invention aims to provide an improved method for fabricating a low temperature polysilicon thin film transistor without residues of photoresist and chemicals.

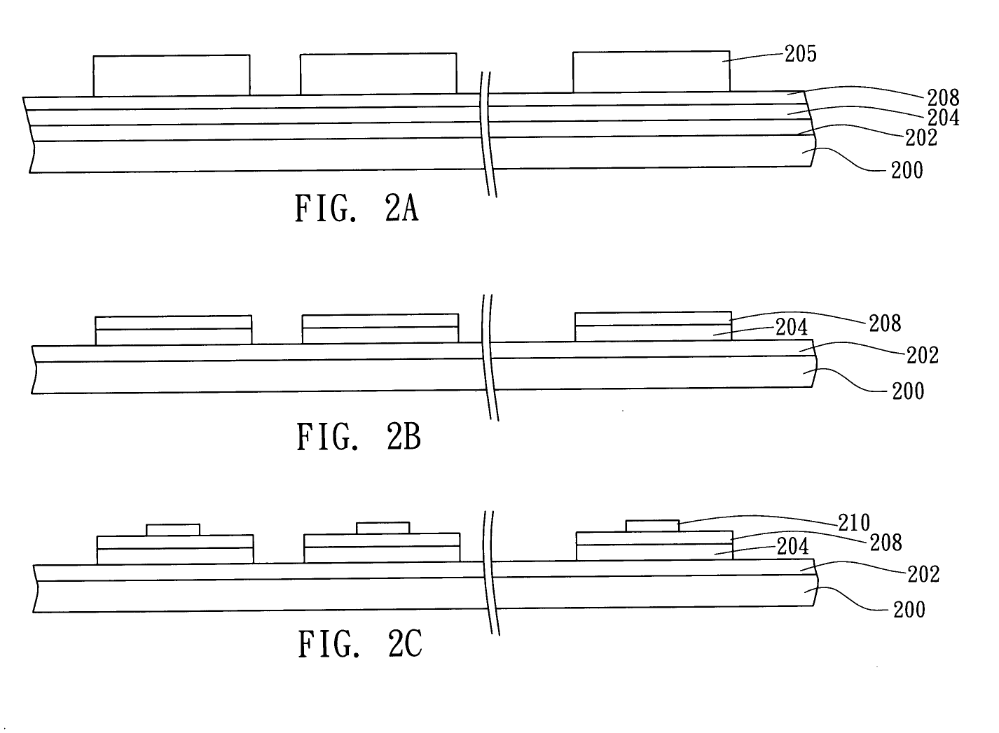

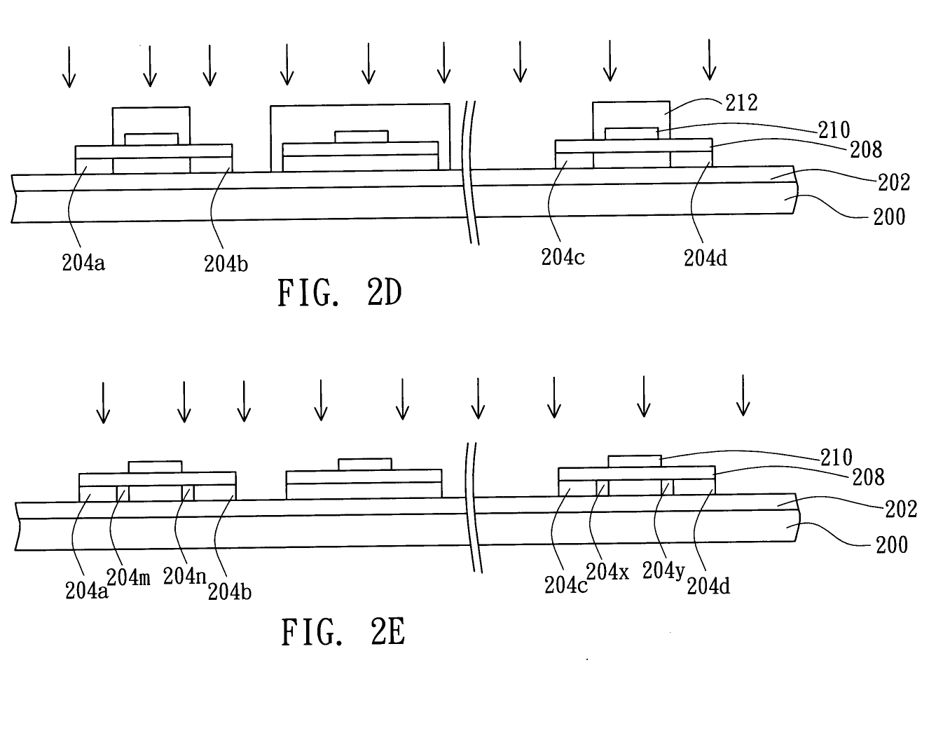

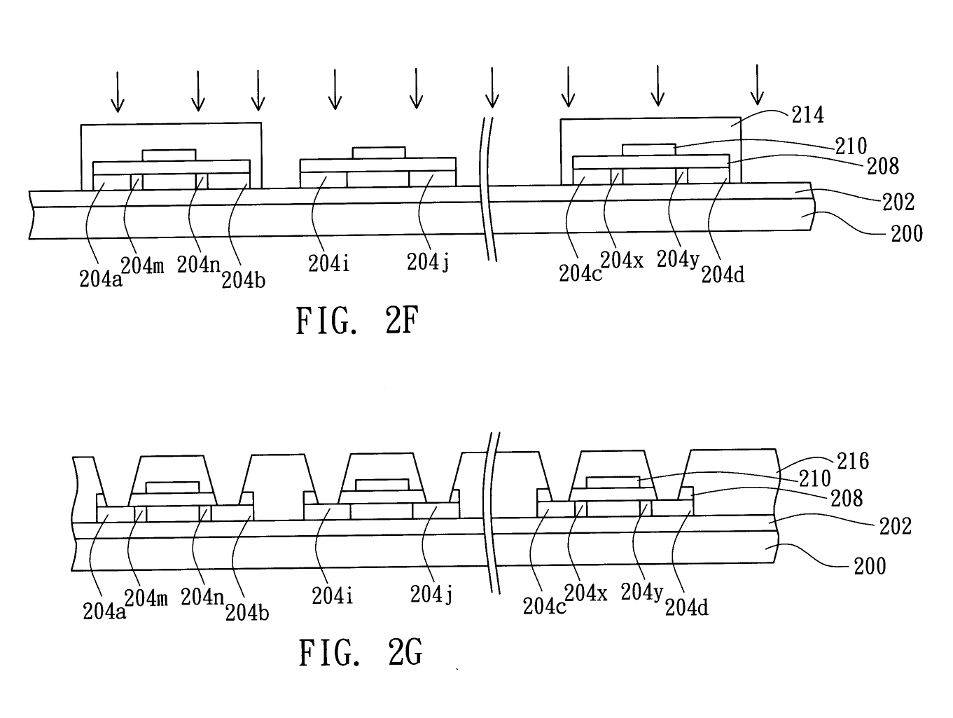

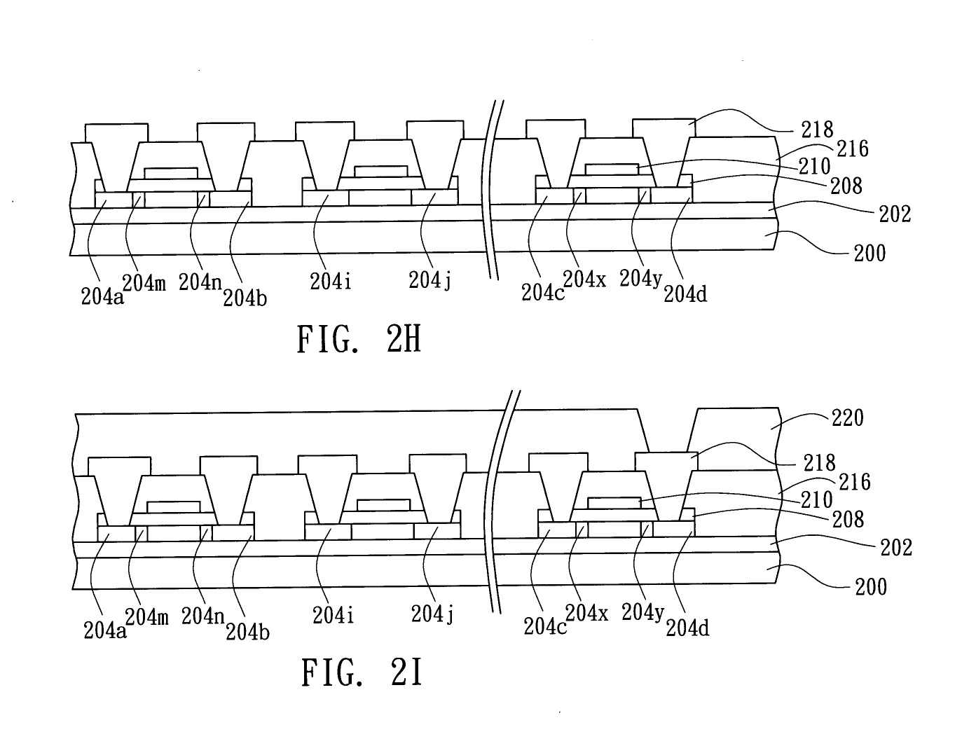

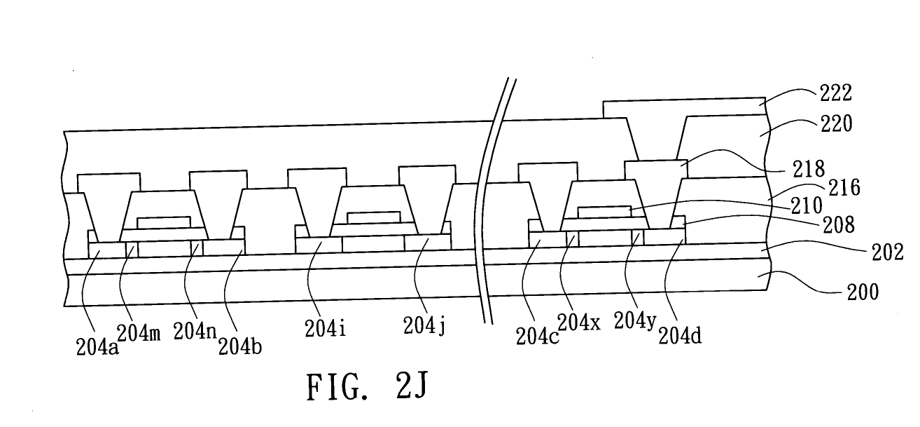

FIGS. 2A to 2J are cross-sectional views showing the sequential process steps of the method for fabricating a low temperature polysilicon thin film transistor in accordance with one preferred embodiment of the present invention. Referring first to FIG. 2A, a buffer layer 202 and a polysilicon layer 204 are sequentially formed on a substrate 200. The buffer layer 202 can be a silicon oxide layer or a silicon nitride layer, and the substrate 200 can be a glass substrate or a plastic substrate. The polysilicon layer 204 can be formed by annealing amorphous silicon using excimer laser. The polysilicon layer 204 can have a thickness between about 200 angstroms and 1000 angstroms.

Next, a gate oxide layer 208 is formed on the polysilicon layer 204. The gate oxide layer 208 can be made of silicon dioxide, and can have a thickness between about 500 angstroms and 1500 angstroms. Then, a patterned photoresist layer 205 is formed on the polysilicon layer 204, and the gate oxide layer 208 and the polysilicon layer 204 are etched using the patterned photoresist layer 205 as a mask. The removal of the residues of the photoresist layer 205 on the gate oxide layer 208 is performed by using chemicals, such as wet dip. The structure after wet dip is shown in FIG. 2B. In FIG. 2B, there are three stack structures having the gate oxide layer 208 and the polysilicon layer 204. The middle and the left ones respectively function as the NMOS device and the PMOS device of the CMOS transistor. The stack structure on the right of the three stack structures is the NMOS device in the pixel area.

Compared with the conventional manufacturing process, the manufacturing process of the invention has no step between the formation of the polysilicon layer 204 and the gate oxide layer 208. The conventional process includes steps such as forming the photoresist layer 105 on the polysilicon layer 104 and removing the photoresist layer 105 by using chemicals, which do not exist in the method of the present invention. Thus, the problem of photoresist and chemical residues between the gate oxide layer 208 and the polysilicon layer 204 is overcome by applying the process of this invention. This improvement further benefits the quality of the low temperature polysilicon TFTs.

Referring to FIG. 2C, a conductive layer is disposed on the gate oxide layer 208. Photolithography and etching processes are then performed to define the patterned conductive layer and form a gate 210. The material of the gate 210 can be molybdenum (Mo), chromium (Cr), thallium/aluminum/thallium (Ti/Al/Ti) or their combination. Next, referring to FIG. 2D, a patterned photoresist layer 212 is formed on the gate 210 and on the gate oxide layer 208. Then, a heavily doping process, using high dosage of phosphorus, is performed to form source/drain regions 204a, 204b, 204c, 204d of a NMOS transistor. The dosage of phosphorus implanted can be between about 1E14 dose/cm² and 5E15 dose/cm².

The photoresist layer 212 then is removed. Low dosage of phosphorus is then implanted into the substrate 200 to form a lightly doped source/drain regions 104m, 104n, 104x, 104y of the NMOS transistor, as shown in FIG. 2E. The dosage of phosphorus implanted is between about 8E12 dose/cm² and 5E13 dose/cm². Next, referring to FIG. 2F, a photoresist layer 214 is formed over the substrate 200 on the gate 210 and the gate oxide layer 208. Using the photoresist layer 214 as a mask, high dosage of boron is implanted in the substrate 200 to form source/drain region 204i, 204j of a PMOS transistor. The dosage of boron implanted is between about 1E14 dose/cm² and 5E15 dose/cm².

Referring to FIG. 2G, the photoresist layer 214 is removed. An interlayer dielectric 216 is formed on the gate 210 and on the gate oxide layer 208. There are a number of openings formed within the gate oxide layer 208 and within the interlayer dielectric 216 thereon. The interlayer dielectric 216 can be made of silicon dioxide, and can have a thickness between about 2000 angstroms and 7000 angstroms. Then, referring to FIG. 2H, a conductive layer, filling the openings within the gate oxide layer 208 and the interlayer dielectric 116, is formed on the interlayer dielectric 216. The conductive layer forms electrodes 218 electrically connecting the gate 210, the source/drain regions 204a, 204c, 204i, 204b, 204d and 204j.

Referring to FIG. 21, a passivation layer 220 is formed on the electrodes 218 and on the interlayer dielectric 216. An opening formed within the passivation layer 220 exposes a part of the electrodes 218. Next, a transparent electrode 222 is formed on the passivation layer 220 and fills in the opening through the passivation layer 220 to electrically connect the electrode 218, as shown in FIG. 2J. The transparent electrode 222 can be made of a conductive transparent material such as indium tin oxide (ITO).

With the abovementioned manufacturing process, the residues of photoresist and chemicals on the polysilicon layer 204 can be effectively prevented. The electron mobility of the low temperature polysilicon TFT is improved as a result of the improved smooth interface between the polysilicon layer 204 and the gate oxide layer 208. Some other defects occurring on the devices manufactured by the conventional method, such as abnormal shifting of the threshold voltage and sub-threshold swing, are effectively prevented.

While the invention has been described by way of example and in terms of a preferred embodiment, it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for fabricating a low temperature polysilicon thin film transistor, comprising:
providing a substrate;
forming a polysilicon layer on the substrate;
forming a gate oxide layer on the polysilicon layer;
forming a photoresist pattern on the gate oxide layer;
etching the polysilicon layer and the gate oxide layer using the photoresist pattern as a mask;
removing the photoresist pattern;
forming a gate on the gate oxide layer; and
implanting dopants to form a source/drain region using the gate as a mask.

2. The method according to claim 1, further comprising forming a buffer layer on the substrate prior to forming the polysilicon layer on the substrate.

3. The method according to claim 1, wherein the polysilicon layer has a thickness between about 200 angstroms and 1000 angstroms.

4. The method according to claim 1, wherein the gate oxide layer has a thickness between about 500 angstroms and 1500 angstroms.

5. The method according to claim 1, wherein the gate comprises molybdenum (Mo), chromium (Cr), thallium/aluminum/thallium (Ti/Al/Ti), or a combination thereof.

6. The method according to claim 1, wherein the dosage of the dopants implanted is between about 1E14 dose/cm² and 5E15 dose/cm².

7. A method for fabricating a first type transistor and a second type transistor on a substrate, comprising:
forming a polysilicon layer on the substrate;
forming a gate oxide layer on the polysilicon layer;
forming a photoresist pattern on the gate oxide layer;
etching the polysilicon layer and the gate oxide layer to form a first stack structure corresponding to the first type transistor and a second stack structure corresponding to the second type transistor using the photoresist pattern as a mask;
removing the photoresist pattern;
forming a gate, occupying a smaller region than the gate oxide layer, on the gate oxide layer;
forming a source/drain region by implanting first heavy dopants in the first type transistor beside the gate and using a photoresist layer covering the second stack structure and a lightly doped region of the first type transistor as a mask;
implanting first dopants in the first type transistor to form the lightly doped region using the gate as a mask; and
forming a source/drain region of the second type transistor by implanting second heavy dopants using a photoresist layer over the first stack structure as a mask.

8. The method according to claim 7, further comprising forming a buffer layer on the substrate prior to forming the polysilicon layer on the substrate.

9. The method according to claim 7, after forming the source/drain region of the second type transistor, further comprising:
forming an interlayer dielectric on the gate oxide layer, the gate and the substrate;
selectively exposing the gates, the source/drain regions of the first type transistor and the second type transistor; and
forming electrodes to electrically connect the gate and the source/drain region of the first type transistor and electrically connect the gate and the source/drain region of the second type transistor, respectively.

10. The method according to claim 9, wherein the interlayer dielectric has a thickness between about 2000 angstroms and 7000 angstroms.

11. The method according to claim 9, wherein the gate comprises molybdenum (Mo), chromium (Cr), thallium/aluminum/thallium (Ti/Al/Ti), or a combination therof.

12. The method according to claim 9, after forming the electrodes, further comprising:
forming a patterned passivation layer on the interlayer dielectric and the electrodes, wherein the patterned passivation layer exposes a portion of the electrode of the first type transistor located within a pixel area; and
forming a transparent electrode to electrically connect the exposed portion of the electrode of the first type transistor.

13. The method according to claim 12, wherein the transparent electrode comprises indium tin oxide (ITO).

14. The method according to claim 7, wherein the polysilicon layer has a thickness between about 200 angstroms and 1000 angstroms.

15. The method according to claim 7, wherein the gate oxide layer has a thickness between about 500 angstroms and 1500 angstroms.

16. The method according to claim 7, wherein the gate comprises molybdenum (Mo), chromium (Cr), thallium/aluminum/thallium (Ti/Al/Ti), or a combination thereof.

17. The method according to claim 7, wherein the dosage of the first heavy dopants is between about 1E14 dose/cm² and 5E15 dose/cm².

18. The method according to claim 7, wherein the dosage of the first light dopants implanted is between about 8E12 dose/cm² and 5E13 dose/cm².

19. The method according to claim 7, wherein the dosage of the second heavy dopants implanted is between about 1E14 dose/cm² and 5E15 dose/cm².

20. The method according to claim 7, wherein the first type transistor is a NMOS transistor and the second type transistor is a PMOS transistor.
